(19) United States
(12) Patent Application Publication
(10) Pub. No.: US 2024/0192254 A1
(43) Pub. Date: Jun. 13, 2024

(54) MEASURING DEVICE FOR A CURRENT CONVERTER

(71) Applicant: Maschinenfabrik Reinhausen GmbH, Regensburg (DE)

(72) Inventors: Erik Winkelmann, Dresden (DE); Iaroslav Shevchenko, Dresden (DE)

(21) Appl. No.: 18/554,202

(22) PCT Filed: Mar. 22, 2022
(86) PCT No.: PCT/EP2022/057437

§ 371 Date: Oct. 6, 2023

(30) Foreign Application Priority Data
Apr. 9, 2021 (DE) 10 2021 108 860.7

(51) Int. Cl. G01R 15/18

(52) U.S. Cl. CPC G01R 15/183; G01R 15/186

(57) ABSTRACT

A measuring device that is for a current transformer includes a surrounding core; a measuring coil; and a reference connection. The measuring coil has a current conductor wound around the surrounding core that extends from a first conductor end to a second conductor end. The reference connection is electrically conductively connected to the current conductor centrally between the first conductor end and the second conductor end.

### CROSS REFERENCE TO RELATED APPLICATIONS

This application is a U.S. National Phase application under 35 U.S.C. § 371 of International Application No. PCT/EP2022/057437, filed on Mar. 22, 2022, and claims benefit to German Patent Application No. DE 10 2021 108 860.7, filed on Apr. 9, 2021. The International Application was published in German on Oct. 13, 2022 as WO 2022/214307 A1 under PCT Article 21(2).

### FIELD

The present disclosure relates to a measuring device for a current transformer.

### BACKGROUND

Current transformers are known in principle. A current transformer has a measuring device. The measuring device may be used to contactlessly detect a primary current through an electrical primary power line. By way of example, the primary power line may be formed by a cable, in particular a copper cable, through which the primary current flows. In order to detect the primary current using the measuring device of the current transformer, the primary power line is passed through the measuring device. In one embodiment, the measuring device has a surrounding annular core, with a measuring coil of the measuring device being formed by a current conductor wound around the core. This current conductor may also be referred to as a secondary power line of the measuring device. In the cited example, the primary power line may be passed through the interior space formed by the core. The primary current flowing through the primary power line causes a secondary current in the secondary power line of the measuring device through electromagnetic induction. The secondary current is smaller than the primary current, specifically preferably inversely proportional to the ratio of the turns number of the primary power line to the turns number of the secondary power line.

It has been identified, during practical use of a current transformer, that electromagnetic interference fields may affect the secondary current. In other words, the secondary current may have a component caused by interference. This component may also be referred to as interference component of the secondary current. The interference component reduces the measurement accuracy with which the primary current is able to be detected by way of the current transformer.

### SUMMARY

In an embodiment, the present disclosure provides a measuring device that is for a current transformer and includes a surrounding core; a measuring coil; and a reference connection. The measuring coil has a current conductor wound around the surrounding core that extends from a first conductor end to a second conductor end. The reference connection is electrically conductively connected to the current conductor centrally between the first conductor end and the second conductor end.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic sectional illustration of one advantageous embodiment of the measuring device;

FIG. 2 shows a schematic block diagram of the advantageous embodiment of the measuring device;

FIG. 3 shows a schematic sectional illustration of one advantageous embodiment of the core of the measuring device;

FIG. 4 shows a schematic illustration of a first advantageous embodiment of a section of the core;

FIG. 5 shows a schematic illustration of a second advantageous embodiment of a section of the core;

FIG. 6 shows a schematic sectional illustration of a second advantageous embodiment of the measuring device;

FIG. 7, FIG. 8 and FIG. 9 each show a schematic illustration of one advantageous embodiment of the current transformer;

FIG. 10 shows a schematic sectional illustration of a third advantageous embodiment of the measuring device;

FIG. 11 shows a schematic sectional illustration of a fourth advantageous embodiment of the measuring device;

FIG. 12 shows a schematic sectional illustration of a fifth advantageous embodiment of the measuring device; and

FIG. 13 and FIG. 14 show one advantageous embodiment of the first shield of the measuring device.

### DETAILED DESCRIPTION

The present disclosure provides a measuring device for a current transformer, which measuring device permits detection of a current that is as robust as possible to interference variables.

According to a first aspect of the present disclosure, a measuring device for a current transformer is provided, wherein the measuring device has a surrounding core, a measuring coil and a reference connection. The measuring coil is formed by a current conductor that is wound around the core and that extends from a first conductor end to a second conductor end. The reference connection is electrically conductively connected to the current conductor centrally between the first conductor end and the second conductor end. The measuring coil is preferably electrically insulated from the core. The current conductor may thus, for example, be electrically insulated from the core.

The measuring device is preferably designed to form part of a current transformer. The measuring device may thus be electrically connected to further parts of the current transformer by way of the associated conductor ends (first and second conductor end).

The current conductor, wound around the core, of the measuring device may be referred to and/or designed as the secondary power line. A current flowing through the current conductor wound around the core may be referred to as secondary current. When a primary current conductor is guided through the interior space formed by the core and a primary current flows through the primary current conductor, this primary current causes the secondary current in the current conductor of the measuring device through electromagnetic induction. The induction preferably takes place here over the entire length of the current conductor of the measuring device. The reference connection electrically connected to the current conductor of the measuring device centrally between the first conductor end and the second conductor end is preferably used to generate a differential signal at the two conductor ends when the abovementioned electromagnetic induction leads to a secondary current in the current conductor of the measuring device. The reference connection may be coupled to a predetermined electrical voltage potential, which is also referred to as reference voltage potential. The voltage signal generated at the two conductor ends then refers to the reference voltage signal predetermined by the reference connection. For example, if the reference voltage connection is connected to ground potential, then for example a positive current is caused at the first conductor end through the electromagnetic induction, whereas a negative current is caused at the second conductor end through the electromagnetic induction, or vice versa. The voltage potential at the two conductor ends is likewise different. If the reference voltage potential is again assumed to be the ground potential, the voltage potential at the first conductor end may have an inverse mathematical sign to the voltage potential at the second conductor end. The reference voltage potential is in principle not necessarily the ground potential. On the contrary, any voltage potential may be applied at the reference connection.

Electromagnetic interference that acts from the outside on the measuring device, and in particular on the measuring coil, may cause a common-mode interference current in the measuring coil. The central arrangement of the reference connection ensures that the interference current is injected uniformly onto the two partial lengths of the current conductor wound around the core. The partial lengths are understood to mean the first partial length of the current conductor extending from the reference connection to the first conductor end, and the second partial length of the current conductor extending from the reference connection to the second conductor end. If the measuring device is coupled to a differential amplifier of the current transformer in order to measure the secondary current of the current conductor of the measuring device, then the common-mode interference current causes no or only a small interference component at the output of the differential amplifier. The output signal of the differential amplifier is therefore not or only slightly affected by the electromagnetic interference acting on the measuring device, due to the centrally arranged reference connection. The measuring device thus contributes to the primary current of a primary power line being able to be detected, by way of a current transformer comprising the measuring device, in a manner robust to electromagnetic inference acting from the outside on the measuring device.

The central arrangement of the reference connection between the first conductor end and the second conductor end may, in one advantageous embodiment, mean that the first partial length of the current conductor extending from the reference connection to the first conductor end and the second partial length of the current conductor extending from the reference connection to the second conductor end are identical or have a deviation of at most 5% or at most 10%. For instance, the first partial length may for example be at most 5% or at most 10% longer than the second partial length, or vice versa.

Preferably, the current conductor of the measuring device is formed by an electrically conductive wire. The wire may for example be designed as a copper wire.

Preferably, the core of the measuring device is designed as a circular core in terms of its outer cross section or as a rectangular core in terms of its outer cross section. The core of the measuring device may also be designed and/or referred to as an annular core. Preferably, the core of the measuring device forms a ring that runs around in the circumferential direction of the core, in particular in the manner of a toroid. The ring may also be designed as a rectangular ring.

The current conductor may be wound around the core such that multiple winding sections are formed, these being connected in series by way of the current conductor and thereby together forming the measuring coil. The measuring coil may also be referred to as measuring winding and/or be designed as such. Each winding section preferably comprises multiple turns of the current conductor. Preferably, the measuring coil is formed exclusively by the uninterrupted current conductor wound around the core.

Preferably, the measuring coil of the measuring device is formed by at least two symmetrically arranged winding sections. Further winding sections may also be provided in principle. The winding sections are preferably distributed in the circumferential direction of the core such that the current conductor is wound around the core in a manner distributed uniformly in the circumferential direction of the core. It has proven to be advantageous when the measuring coil is formed for example from four winding sections. The winding sections are connected in series and thereby form the measuring coil. The current conductor extends here from winding section to winding section. The reference connection may be connected to the current conductor between two of the multiple winding sections of the measuring coil. This facilitates a particularly precise central arrangement of the reference connection between the first conductor end and the second conductor end of the current conductor.

One advantageous embodiment of the measuring device is distinguished in that the reference connection is electrically connected to the current conductor such that a first impedance of the current conductor between the reference connection and the first conductor end and a second impedance of the current conductor between the reference connection and the second conductor end are identical or have a maximum deviation of 5% or 1%. According to this embodiment, provision is preferably made for the maximum deviation of the impedances of the first and second partial lengths of the current conductor to be at most 5%. Preferably, the current conductor has a diameter that is at least substantially constant. The abovementioned limitation with regard to the deviation of the impedances particularly advantageously makes it possible to ensure that an electromagnetic interference signal acting from the outside on the measuring device is distributed equally over the two partial lengths of the current conductor, such that the same interference component is injected in each of the two current conductors. These interference components cause a common-mode interference current that is not amplified at a differential amplifier as a common-mode signal or, at most, leads to slight interference at the output of the differential amplifier.

A further advantageous embodiment of the measuring device is distinguished in that the reference connection is connected to a predetermined electrical reference potential. By way of example, the reference potential may be a predetermined voltage or may be formed by ground potential.

A further advantageous embodiment of the measuring device is distinguished in that the measuring coil is arranged in a manner distributed symmetrically with respect to a radial plane of the core. A central opening is preferably formed by the surrounding core. A longitudinal axis of the core may run in a direction of passage through this central opening of the core. The direction of passage is therefore also referred to as axial direction of the core. A radial direction of the core is perpendicular to the axial direction of the core. This preferably applies even if the core is not designed as a circular core, but rather if the core for example has a rectangular cross section. The radial plane of the core is preferably spanned by the axial direction of the core and the radial direction of the core. The symmetrical distribution of the measuring coil with respect to the radial plane of the core offers the advantage that the electrical properties of the first partial length of the current conductor and the electrical properties of the second partial length of the current conductor are at least substantially identical or at most have a deviation of at most 5%. By way of example, it is thus possible for the symmetrical distribution to contribute to the first and second impedance being identical or having a maximum deviation of 5%. The same may apply to the lengths, electrical resistances and/or the turns numbers of the first and second partial length of the current conductor.

A further advantageous embodiment of the measuring device is distinguished in that the core includes or is formed from magnetic, in particular ferromagnetic, and/or amorphous material. Preferably, the core consists to at least 80%, 90% or 95% of magnetic, in particular ferromagnetic material. The remaining part of the core may be formed by a non-ferromagnetic material or substance. Iron, cobalt and nickel are ferromagnetic. They therefore form exemplary magnetic or ferromagnetic metals. The magnetic material of the core may be formed by one or more magnetic metals. The magnetic material of the core is particularly preferably formed to at least 80%, 90% or 95% by MgZn ferrite. The material of the core may furthermore be formed as an amorphous material. It has proven to be particularly advantageous when the material of the core in which a magnetic circuit forms is formed of ferromagnetic and/or amorphous material. Magnetic material is preferably understood to mean magnetizable material. This material does not have to be designed to cause a magnetic field.

A further advantageous embodiment of the measuring device is distinguished in that the core is of multi-part design. By way of example, the core may thus be formed of multiple parts. A first part of the core may for example be designed as a part with a C-shaped cross section. A second part of the core may for example be designed as a part with an I-shaped cross section. The I-shaped part may be arranged on the C-shaped part such that the two parts of the core form a core that runs around with a rectangular cross section and that encloses a interior space that is laterally open. The parts of the core may be arranged in direct contact with one another.

A further advantageous embodiment of the measuring device is distinguished in that the measuring coil is of multi-part design. The measuring coil is basically formed by the current conductor wound around the core. The current conductor extends in uninterrupted form from the first conductor end to the second conductor end. However, the current conductor may comprise at least one detachable connection point. Preferably, the current conductor comprises multiple detachable connection points. At each connection point, the continuous connection of the current conductor may for example be interrupted and restored for the installation of the measuring device. The current conductor may be wound around the core such that multiple winding sections are formed, these being connected in series by way of the current conductor and thereby together forming the measuring coil. By way of example, the measuring coil may have three winding sections. The first winding section of the measuring coil may for example be formed by the current conductor such that the current conductor extends in the first winding section from the first conductor end to a first connection end. The second winding section of the measuring coil may for example be formed by the current conductor such that the current conductor extends in the second winding section from a second connection end to a third connection end. The third winding section of the measuring coil may for example be formed by the current conductor such that the current conductor extends in the third winding section from a fourth connection end to the second conductor end. A first detachable connection point of the current conductor may for example be formed by the first and second connection end, which are connected detachably to one another. A second detachable connection point of the current conductor may for example be formed by the third and fourth connection end, which are connected detachably to one another. The two connection points ensure that the current conductor extends continuously and/or in uninterrupted form from the first conductor end to the second conductor end. The current conductor may be interrupted at the connection points, in particular for installation or for manufacturing purposes. By way of example, it has thus proven to be advantageous when the first and third winding section of the current conductor are arranged on the C-shaped part of the core. The part of the current conductor forming the first winding section may thus be wound around a first limb of the C-shaped part of the core. A part of the current conductor forming the third winding section may be wound around a second limb of the C-shaped part of the core. A part of the current conductor forming the second winding section may be wound around the I-shaped part of the core. If the C-shaped part and the I-shaped part of the core are arranged with respect to one another so as to form the surrounding core, then provision may furthermore be made for the first and second connection end to be connected to form the first detachable connection point of the current conductor. The third and fourth connection end may furthermore be connected to one another to form the second detachable connection point of the current conductor. If the two connection points are produced, the current conductor wound around the surrounding core extends from the first conductor end to the second conductor end.

The measuring coil may also be referred to as measuring winding and/or be designed as such. Each winding section preferably comprises multiple turns of the current conductor. Preferably, the measuring coil is formed exclusively by the uninterrupted current conductor wound around the core.

A further advantageous embodiment of the measuring device is distinguished in that the core has at least one section having a plurality of magnetic plates that are arranged opposite one another, in particular so as to be parallel, and are each spaced by a gap from plate to plate. The magnetic plates are preferably designed as ferromagnetic plates. It has proven to be advantageous that it is possible to prevent the potential problem of saturation of the core in the case of a primary current through the primary power line with a frequency equal to or higher than the operating frequency when the magnetic permeability of the core is small. By way of example, the operating frequency is less than 100 Hz. In order to achieve a reduction in the magnetic permeability of the core, provision is therefore made for the multiple gaps between the plates. The multiple gaps cause the magnetic permeability of the core to decrease, which may prevent the problem of saturation of the core. It should be taken into account that the core in this embodiment is formed by the plurality of magnetic, in particular ferromagnetic plates and the gaps. Preferably, each gap between two plates arranged opposite one another is designed in each case such that the plates are arranged without contact with one another and/or the maximum distance between the plates is less than 1 mm, less than 0.5 mm, or less than 0.1 mm. Preferably, the distance between the plates arranged without contact with one another is in each case between 0.02 mm and 0.08 mm, preferably between 0.05 mm and 0.06 mm. Each gap may be referred to and/or designed as a non-magnetic or non-ferromagnetic gap. Preferably, the gaps are arranged in a manner distributed symmetrically with respect to the radial plane of the core. Provision is furthermore preferably made for the plates of the core to be arranged in a manner distributed symmetrically with respect to the radial plane of the core.

A further advantageous embodiment of the measuring device is distinguished in that the core has multiple sections each having a plurality of magnetic, in particular ferromagnetic plates, wherein the plates of the respective section are arranged opposite one another, in particular so as to be parallel, and in direct contact from plate to plate, and wherein the sections of the core are arranged in succession and spaced by a gap from section to section. A core with a rectangular cross section may have four edges (for example two parallel horizontal edges and two parallel vertical edges). At least one of the edges may be divided into at least two parts. The core with a rectangular cross section may thus for example have five sections, each having a plurality of plates. However, it is also possible for the core to have a smaller or larger number of sections. Each edge of the core may thus in turn be divided into a multiplicity of sections. Provision is preferably made for the plates of a respective section to be arranged in direct contact from plate to plate and thus in succession. In an edge, multiple sections, each having a plurality of magnetic, in particular ferromagnetic plates, may be arranged in succession, wherein the sections are spaced by a respective gap from section to section. Each gap separates the plate located at an adjacent end of a section from an opposing plate of the following section. Within each section, provision is preferably made for the plates to be arranged in succession without gaps. Each section may for example comprise between two plates and 50 plates, in particular between five plates and 30 plates, preferably between five plates and 15 plates. It should be noted that the core may have a large number of sections, with the abovementioned features of the sections referring in particular only to a subset of this larger number of sections. However, it is also possible for the abovementioned features to refer to each section of the core. For the gap formed from section to section, reference is made to the advantageous explanations, preferred features, effects and advantages in the same way as explained previously for the gap from plate to plate.

A further advantageous embodiment of the measuring device is distinguished in that each gap is formed as an air gap or a spacer is inserted into each gap. If a spacer is inserted into a gap, the respective gap may be formed completely by the spacer. Each spacer may be made of paper, in particular laminated paper, or plastic, in particular fiberglass plastic.

A further advantageous embodiment of the measuring device is distinguished in that each spacer is formed of a non-ferromagnetic material. This makes it possible to reduce or even prevent the potential problem of saturation of the core.

A further advantageous embodiment of the measuring device is distinguished in that the plates of each pair of plates spaced by a gap are arranged in a manner spaced from one another without contact, with a plate distance between at least 0.001 mm and at most 0.7 mm. A magnetic flux arising when current flows through the primary power line is thereby bundled and guided with low loss.

A further advantageous embodiment of the measuring device is distinguished in that the measuring device has a first shield, which has a first protective element and preferably a second protective element. The first shield may also be referred to as first shielding device and/or be designed as such. The first shield forms part of the measuring device. The first shield may be formed exclusively by the first protective element. However, it is also possible for the first shield, in addition to the first protective element, to comprise further parts, in particular the second protective element. The first shield may be used and/or designed to prevent and/or attenuate electromagnetic interference acting from the outside on the measuring device. Provision may furthermore be made for the first shield to be designed to prevent electromagnetic fields from penetrating the first shield and emitting into the environment as electromagnetic interference. The first protective element is preferably designed as a shielding metal plate or as a shielding grating. The first shield may include the first protective element and the second protective element and/or be formed completely by these protective elements. However, it is also possible for the first shield to be formed just by the second protective element. The second protective element is preferably designed as a shielding metal plate or as a shielding grating.

A further advantageous embodiment of the measuring device is distinguished in that the first protective element is designed as an electrically conductive protective element that is arranged outside the core and the measuring coil and that runs around at least substantially completely in the circumferential direction of the core. The first protective element is preferably arranged outside the core and/or the measuring coil in the radial direction. Preferably, the first protective element is not in direct contact with the measuring coil and/or the core. On the contrary, provision is preferably made for the first protective element to be spaced from the measuring coil and/or the core. Provision is preferably furthermore made for the first protective element to be electrically conductive. At least part of a cage, in particular a Faraday cage, may thus be formed by the first protective element, and be arranged outside the core and run at least substantially completely around the core in the circumferential direction. The first protective element offers protection against electromagnetic interference for the measuring coil and/or the core. Preferably, the first protective element is interrupted at one point in the circumferential direction. As an alternative, however, it is also possible for the first protective element to be designed to run around completely and/or without an interruption in the circumferential direction of the core.

A further advantageous embodiment of the measuring device is distinguished in that the second protective element is designed as an electrically conductive protective element that is arranged inside the core and the measuring coil and that runs around at least substantially completely in the circumferential direction of the core. The second protective element is preferably arranged inside the core and/or the measuring coil in the radial direction. The second protective element may thus be arranged at least partially or completely in the interior space, which is enclosed by the core of the measuring device. Preferably, the second protective element is not in direct contact with the measuring coil and/or the core. On the contrary, provision is preferably made for the second protective element to be spaced from the first measuring coil and/or the core. Provision is preferably furthermore made for the second protective element to be electrically conductive. At least part of a cage, in particular a Faraday cage, may thus be formed by the second protective element, and be arranged in the interior space of the core and/or be designed to run around at least substantially completely in the circumferential direction of the core. The first protective element offers protection against electromagnetic interference for the measuring coil and/or the core. Preferably, the second protective element is interrupted at one point in the circumferential direction. As an alternative, however, it is also possible for the second protective element to be designed to run around completely and/or without an interruption in the circumferential direction of the core.

A further advantageous embodiment of the measuring device is distinguished in that the first shield is designed as an annular shield that runs around in the circumferential direction of the core and that encloses the core and the measuring coil at least substantially in the shape of a tube, wherein the annular shield is formed by two shell-shaped protective elements, each running around in the circumferential direction of the core, which form the first and second protective element. Preferably, the cross-sectional surface of the annular shield oriented perpendicular to the circumferential direction is rectangular, in particular square. Since the core and the measuring coil are at least substantially enclosed in the shape of a tube by the annular shield, it is possible to achieve particularly effective shielding against electromagnetic interference. It has furthermore proven to be advantageous when the annular shield is designed to run around in a rectangular shape. This is particularly true when the core is designed as a core that runs around in a rectangular shape. The annular shield is preferably divided in a separating plane in which the circumferential direction of the core runs around. The division of the annular shield in the separating plane means that the annular shield forms the first and second shell-shaped protective element each running around in the circumferential direction. In the separating plane, the first and second protective element are preferably detachably connected to one another. However, it is also possible for the first and second protective element to be connected non-detachably to one other, for example welded to one another, in the separating plane. The annular shield having the two shell-shaped protective elements offers the advantage that each of the two shell-shaped protective elements may be pushed over the core and the measuring coil from opposite sides, such that the two shell-shaped protective elements are in contact with one another in the separating plane in order to be able to make electrical and/or mechanical contact here.

A further advantageous embodiment of the measuring device is distinguished in that an outer contour of the annular shield and/or of each shell-shaped protective element is rectangular, and/or wherein an inner contour formed by the annular shield and/or by each shell-shaped protective element is rectangular. As explained above, provision is preferably made for the annular shield to enclose the core and the measuring coil in the shape of a tube. It has proven to be advantageous in practice when the core is designed to run around in a rectangular shape. In order to follow this contour running around in a rectangular shape, it has proven to be advantageous when the outer contour of the annular shield, and thus preferably also the outer contour of each of the two shell-shaped protective elements, is rectangular. An interior space, which is open on opposing sides, is formed by the core, running around in a rectangular shape, of the measuring device. The two shell-shaped protective elements, which likewise run around in the circumferential direction, may engage in this interior space. It has therefore proven to be advantageous when the inner contour of the annular shield and/or the inner contour of each of the two shell-shaped protective elements is rectangular. This is because, in this case, the passage area of the interior space, which passage area is still open between the two opposing sides, is particularly large.

A further advantageous embodiment of the measuring device is distinguished in that the first protective element and the second protective element are electrically connected to one another or are formed integrally as a common protective element. If the first and second protective element are electrically connected to one another, the first and second protective element may form a Faraday cage, which protects the core and the measuring coil from electromagnetic interference. If the first and second protective element are formed integrally or are connected detachably to one another such that they are in electrical contact with one another, then it is possible for the first and second protective element to form a common protective element. The common protective element may run in the circumferential direction of the core in the manner of a torus, such that the core and the measuring coil are arranged within an interior space formed by the protective element. The interior space formed by the common protective element does not necessarily have to be closed. By way of example, it is thus possible for the first protective element and the second protective element each to be formed by a grating, such that the common protective element is also formed by a common grating or by two gratings.

A further advantageous embodiment of the measuring device is distinguished in that the first shield is electrically connected to the reference connection. The reference connection may thus be electrically connected to the first protective element and/or the second protective element. This embodiment is particularly advantageous when the reference connection is coupled to ground potential.

A further advantageous embodiment of the measuring device is distinguished in that a protective distance between the core and/or the measuring coil, on the one hand, and the at least one protective element of the first shield, on the other hand, is predetermined such that a predetermined electrical capacitance is formed between the core and/or the measuring coil, on the one hand, and the first shield, on the other hand. The electrical capacitance influences the transfer function between the measuring device and a differential amplifier of the current transformer. By way of example, the electrical capacitance may thus determine a cutoff frequency of a low-pass characteristic of the transfer function or at least influence same. The predetermined selection of the protective distance makes it possible to set and/or predetermine the electrical capacitance. This furthermore makes it possible to determine the cutoff frequency for the transfer function. With a suitable selection of the cutoff frequency, it is therefore possible to attenuate high-frequency noise or high-frequency interference signals, whereas low-frequency payload signals are transmitted from the measuring device to the differential amplifier. Using the measuring device, it is therefore possible to detect the primary current in a primary current conductor, in a manner robust to high-frequency interference signals, by way of the current transformer.

A further advantageous embodiment of the measuring device is distinguished in that the measuring device may additionally be operated as an infeed device, such that a current is fed into a primary current conductor guided through the interior space formed by the core.

In order to feed the current into the primary current conductor by way of the measuring device, acting in this case as infeed device, of the current transformer, the primary power line is passed through the measuring device and a current is coupled into the current conductor wound around the core. The current flowing through the current conductor causes a current in the primary conductor, which is guided through the measuring device, through electromagnetic induction. It is thus possible, using one and the same measuring device, both to measure a current flowing through the primary current conductor and to feed a current into the primary current conductor.

According to a second aspect of the present disclosure, a current transformer is provided that has a measuring device and a differential amplifier. The measuring device is designed according to the first aspect of the invention and/or one of the associated advantageous embodiments. The current transformer is distinguished in that a first input connection of the differential amplifier is electrically connected to the first conductor end of the current conductor of the measuring device by way of a shielded first connecting line. In addition, a second input connection of the differential amplifier is electrically connected to the second conductor end of the current conductor of the measuring device by way of a shielded second connecting line. The reference connection is preferably coupled, or able to be coupled, to a predetermined electrical reference potential.

Reference is made to the advantageous embodiments, preferred features, effects and/or advantages as have already been explained above for the measuring device according to the first aspect of the present disclosure and/or one of the associated advantageous embodiments for the measuring device of the current transformer.

Preferably, the differential amplifier is designed to generate a measurement signal at the output of the differential amplifier on the basis of the signals at the input connections of the differential amplifier. Preferably, the differential amplifier generates the measurement signal such that the measurement signal represents a primary current flowing through a primary current conductor that passes through an interior space formed by the core of the measuring device. The measurement signal of the differential amplifier may thus form an output signal of the current transformer. The current transformer may have an output connection that is electrically connected to the output of the differential amplifier, such that the measurement signal may be made available at the output connection.

The first and second connecting lines are each shielded. This makes it possible to effectively prevent electromagnetic interference signals acting from the outside on the connecting lines from causing noise on the measurement signal.

The coupling of the reference connection to a predetermined electrical reference potential offers the advantage that the measuring device generates differential signals at the first and second input connection. These may particularly advantageously be used by the differential amplifier to generate the measurement signal at the output of the differential amplifier.

One advantageous embodiment of the current transformer is distinguished in that the reference connection is coupled to ground potential. In principle, however, it is also possible for the reference connection to be coupled to a different predetermined electrical potential than ground potential.

A further advantageous embodiment of the current transformer is distinguished in that each of the two connecting lines has an associated line shield, each of which is coupled to ground potential, wherein the reference connection is separate from the line shields such that no direct electrical connection that does not run via ground potential is formed from the reference potential to at least one of the line shields. Each of the two line connections may be formed by a coaxial cable having a sheath-side shield that forms the respective line shield.

A further advantageous embodiment of the current transformer is distinguished in that the differential amplifier has a second shield that is coupled to ground potential, wherein the second shield is separate from the line shields such that no direct electrical connection that does not run via ground potential is formed from the second shield to at least one of the line shields.

Further features, advantages and possible applications of the present disclosure may be found in the following description of the exemplary embodiments and in the figures. All the features described and/or depicted therein form, individually and in any combination, the subject matter of the present disclosure, irrespective of how they are combined in the individual claims or the dependency references thereof. In the figures, the same reference signs continue to stand for the same or similar objects.

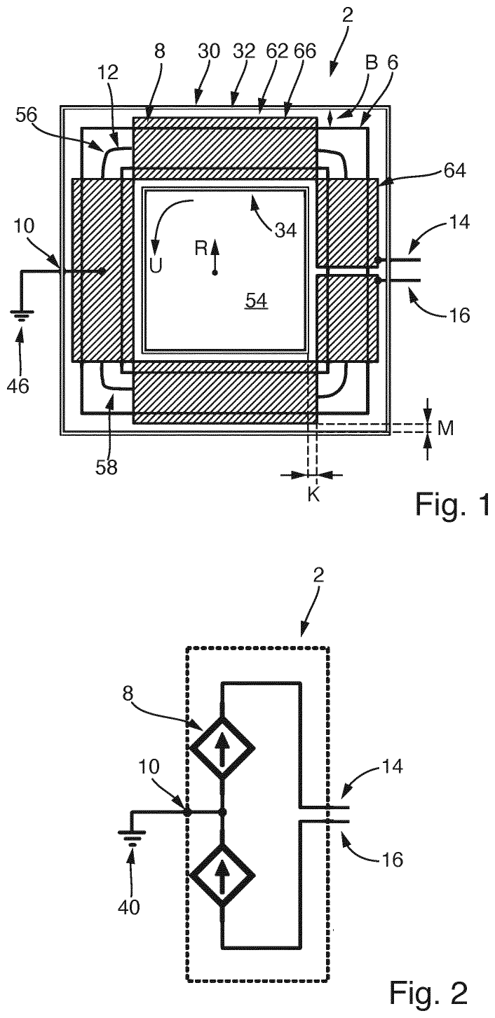

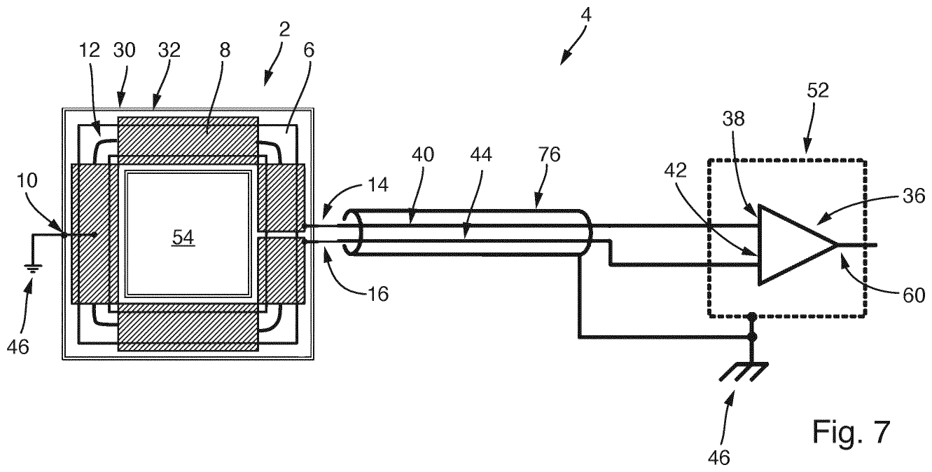

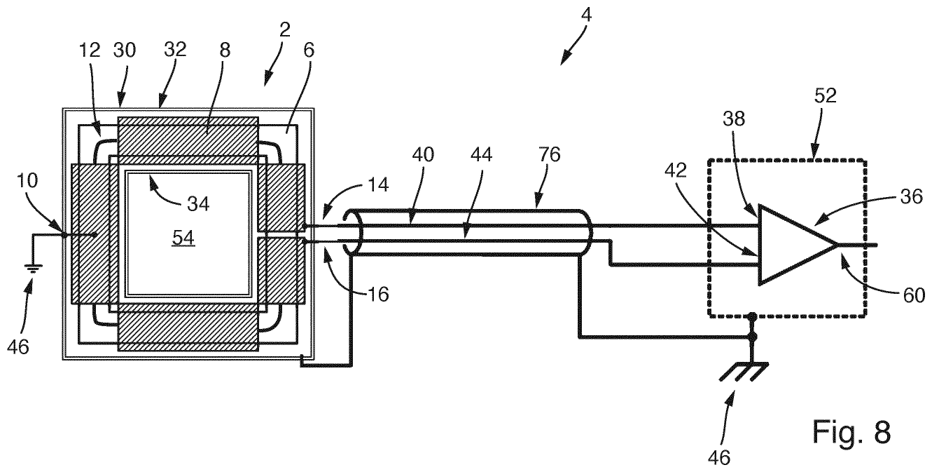

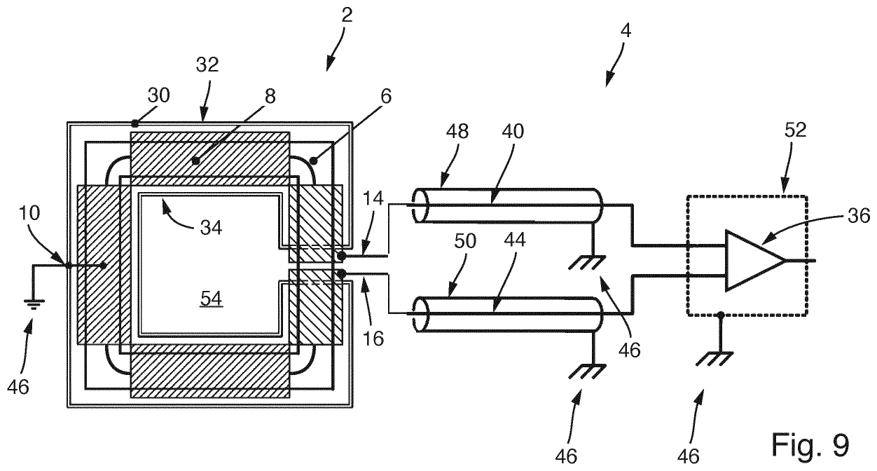

FIG. 1 schematically illustrates a first advantageous embodiment of a measuring device 2. The measuring device 2 is used as measuring device 2 for a current transformer 4, which is illustrated in one advantageous embodiment, for example, in FIG. 7.

The measuring device 2 has a surrounding core 6, a measuring coil 8, and a reference connection 10. The measuring coil 8 is formed by a current conductor 12 wound around the core 6. The current conductor 12 extends in uninterrupted form from a first conductor end 14 to a second conductor end 16. The reference connection 10 is electrically conductively connected to the current conductor 12 centrally between the first conductor end 14 and the second conductor end 16.

The core 6 is formed preferably to at least 80%, at least 90%, or at least 95% of a magnetic, in particular ferromagnetic material, such as for example a MgZn ferrite. As may be seen from FIG. 1, it is also preferable for the core 6 to be designed as a surrounding rectangular core 6. The core 6 thus has an internal interior space 54. The interior space 54 is designed to be open on opposing sides in the axial direction, which is perpendicular to the plane of the page. The radial direction R of the core 6 is perpendicular to the axial direction. A radial plane of the core 6 is spanned by the axial direction and the radial direction R. Reference is made to this radial plane at a certain point.

The current conductor 12 is wound around the core 6 and extends from the first conductor end 14 to the second conductor end 16. The winding of the current conductor 12 around the core 6 gives rise to a multiplicity of turns. The current conductor 12 therefore forms a measuring coil 8 of the measuring device 2. Preferably, the multiplicity of turns of the measuring coil 8 is arranged in a manner distributed in the circumferential direction U of the core 6, in particular arranged in a manner distributed such that an equal number of turns of the measuring coil 8 are arranged on both sides of the radial plane. Particularly preferably, the multiplicity of turns of the measuring coil 8 is arranged in a manner distributed uniformly in the circumferential direction U of the core 6. Provision is preferably furthermore made for the measuring coil 8 to be arranged symmetrically with respect to the radial plane of the core 6. One part of the measuring coil 8 may be arranged on one side of the radial plane and the other part of the measuring coil 8 may be arranged on the other side of the radial plane such that the measuring coil 8 is arranged in a manner distributed symmetrically with respect to the radial plane of the core 6.

As may be seen schematically in FIG. 1, the measuring coil 8 may be formed by multiple winding sections 62 that are electrically connected in series by the current conductor 12. Each of the winding sections 62 has a multiplicity of windings that are formed by the current conductor 12. The current conductor 12 thus extends for example from the first conductor end 14 to a first winding section 64 in which the current conductor 12 is wound around the core 6 in a multiplicity of turns. The current conductor 12 extends from the first winding section 64 to a second winding section 66 in which the current conductor 12 is wound around the core 6 in a multiplicity of turns. A plurality of winding sections 62 may thereby be arranged in a manner distributed in the circumferential direction U of the core 6. The distribution of the winding sections 62 may be configured such that the measuring coil 8 is arranged in a manner distributed symmetrically with respect to the radial plane of the core 6.

The reference connection 10 is electrically connected to the current conductor 12 centrally between the first conductor end 14 and the second conductor end 16. The reference connection 10 may thus be arranged directly on the current conductor 12. However, it is also possible for the reference connection 10 to be arranged at most 10 cm, at most 20 cm, at most 30 cm or at most 40 cm from the center between the first conductor end 14 and the second conductor end 16. This is nevertheless understood to mean that the reference connection 10 is electrically connected to the current conductor 12 centrally between the first conductor end 14 and the second conductor end 16. Centrally between the two conductor ends 14, 16 may mean that a first partial length 56 of the current conductor 12 from the reference connection 10 to the first conductor end 14 and a second partial length 58 of the current conductor 12 from the reference connection 10 to the second conductor end 16 are of identical length or have a deviation in terms of their length of at most 10% or at most 5%.

The current conductor 12 wound around the core 6 may also be referred to as secondary current conductor 12. In one example, if a further primary current conductor is guided in the axial direction through the interior space 54, and a primary current flows through the primary current conductor, then the primary current causes a current in the secondary current conductor 12 through electromagnetic induction, this current also being referred to as secondary current.

The reference connection 10 electrically connected to the current conductor 12 centrally between the two conductor ends 14, 16 offers the advantage that a predetermined electrical potential may be caused at the connection point between the reference connection 10 and the electrical current conductor 12. By way of example, the reference connection 10 may thus be connected and/or coupled to ground potential 46, such that the position of the current conductor 12 that is connected to the reference connection 10 necessarily has the predetermined potential, in this case ground potential 46. The current induced in the current conductor 12 therefore causes what is called a differential current signal at the conductor ends 14, 16. The differential current signal is also referred to as symmetrical current signal or differential-mode current signal. The differential current signal is used as payload signal for the current transformer 4.

However, electromagnetic interference acting from the outside on the measuring device 2 may cause only common-mode interference signals at the conductor ends 14, 16 due to the reference connection 10, which is preferably coupled to a predetermined electrical potential.

If the measuring device 2 is used for a current transformer 4, as illustrated for example and schematically in FIG. 7, then the differential-mode current signal, as payload signal, and the common-mode interference signal reach a differential amplifier 36, which generates an output signal at the output connection 60 of the differential amplifier 36 based on the voltage difference at the input connections 38, 42 of the differential amplifier 36. The common-mode interference signal has no or at most a small influence on the output signal. The output signal is therefore at least substantially characterized by the payload signal. The payload signal is dependent on the primary current through the primary current conductor 12. The measuring device 2 thus offers the advantage that the measuring device 2 contributes to being able to detect the primary current in a manner as robust as possible to external electromagnetic interference.

It has proven to be advantageous when the reference connection 10, which is electrically connected to the current conductor 12 centrally, is electrically connected to the current conductor such that a first impedance of the current conductor 12 between the reference connection 10 and the first conductor end 14 and a second impedance of the current conductor 12 between the reference connection 10 and the second conductor end 16 are identical or have a maximum deviation of 5% or 10%. Particularly preferably, the deviation is at most 5%. It may furthermore be advantageous when the deviation is at most 2%. The smaller the deviation between the first and second impedance, the more accurately the differential payload signal is generated at the conductor ends 14, 16.

FIG. 2 illustrates a schematic block diagram of the first advantageous embodiment of the measuring device 2. As may be seen from the block diagram, the measuring coil 8 is symbolized by two parts, with a respective part being arranged in each partial length between the reference connection 10 and the two conductor ends 14, 16.

To protect the measuring device 2 even better against externally acting electromagnetic interference, provision is preferably made for the measuring device 2 to have a first shield 30. The first shield 30 may also be referred to as first shielding device 30 and/or be designed as such. The first shield 30 preferably has a first protective element 32. The first protective element 32 may be designed as a first protective metal plate 32 or as a first protective grating 32. The first protective element 32 is formed by an electrically conductive material. Provision is preferably furthermore made for the first protective element 32 to be arranged outside the core 6 and the measuring coil 8. The first protective element 32 may thus for example be arranged so as to run around completely in the circumferential direction U of the core 6 and outside the core 6 and the measuring coil 8. The first protective element 32 is not in direct contact with the core 6 and/or the measuring coil 8. On the contrary, provision is preferably made for there to be at least one first minimum distance M between the inside of the first protective element 32 and the least far-away point on the measuring coil 8 and/or the core 6. By way of example, the first minimum distance M may be at least 2 mm, at least 5 mm, or at least 10 mm. The first protective element 32 may form at least part of a Faraday cage for protection against externally acting electromagnetic interference.

The first shield 30 may, as an alternative or in addition, have a second protective element 34. The second protective element 34 may be formed as a second protective metal plate 34 or as a second protective grating 34. The second protective element 34 is formed by an electrically conductive material. Provision is preferably furthermore made for the second protective element 34 to be arranged in the interior space 54. The second protective element 34 may be designed to run around completely in the circumferential direction U of the core 6. The second protective element 34 is not in direct contact with the core 6 and/or the measuring coil 8. On the contrary, provision is preferably made for there to be at least one second minimum distance K between the outside of the second protective element 34 and the least far-away point on the measuring coil 8 and/or the core 6. By way of example, the second minimum distance K may be at least 2 mm, at least 5 mm, or at least 10 mm. The second protective element 34 may form at least part of a or the abovementioned Faraday cage for protection against externally acting electromagnetic interference.

Preferably, the first protective element 32 and the second protective element 34 are electrically connected to one another. The two protective elements 32, 34 may be in direct contact with one another. However, it is also possible for the first protective element 32 and the second protective element 34 to be designed as a common and/or integral protective element. This protective element may thus form both protective elements 32, 34.

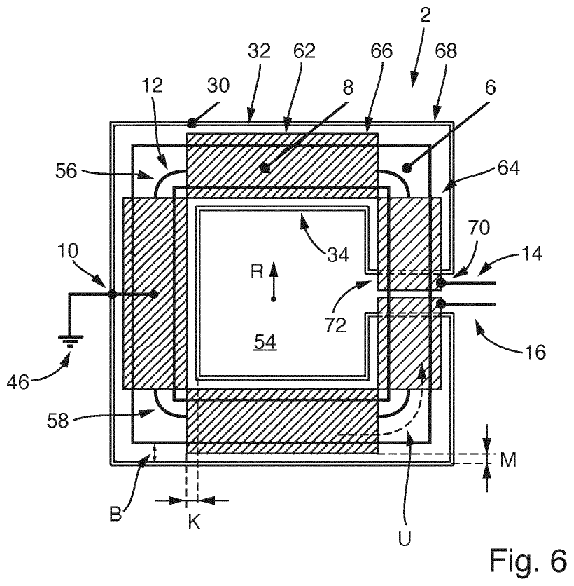

A second advantageous embodiment of the measuring device 2 is illustrated schematically in FIG. 6. This embodiment of the measuring device 2 differs from the measuring device 2 explained above only in terms of the embodiment of the shield 30. Reference is made to the previous explanations for all other advantageous properties, features, advantages and/or effects.

The advantageous embodiment of the shield 30 illustrated in FIG. 6 is formed by a common protective element, wherein this common protective element forms the first protective element 32 and the second protective element 34. The common protective element may be of one-piece design. Provision is preferably furthermore made for the first protective element 32 to be designed not to run around completely in the circumferential direction U of the core 6, but rather to have a first recess 70 extending in the circumferential direction U. The second protective element 34 is likewise designed not to run around completely in the circumferential direction U of the core 6, but rather has a second recess 72 extending in the circumferential direction U. The first and second protective element 32, 34 are electrically and/or mechanically connected to one another in the region of the first and second recess 70, 72.

To positively influence the transmission behavior of the payload signal from the measuring device 2 to the differential amplifier 36, in particular such that only the frequency spectrum of the payload signal, but not the frequency spectrum of the interference signal, is transmitted from the measuring device 2 to the differential amplifier 36, provision is preferably made for an electrical capacitance between the core 6 and/or the measuring coil 8, on the one hand, and the first shield 30, on the other hand, to have a predetermined value. The electrical capacitance is thus preferably predetermined. To achieve this, an average protective distance B between the core 6 and/or the measuring coil 8, on the one hand, and the at least one protective element 32, 34 of the shield 30, on the other hand, is configured such that the predetermined electrical capacitance is achieved. The electrical capacitance is selected here, through the configuration of the average protective distance B, such that the payload signal is transmitted from the measuring device 2 to the differential amplifier 36, but an interference signal that acts from the outside on the measuring device 2 is preferably strongly attenuated and thus reaches the differential amplifier 36 at most with a very small signal level.

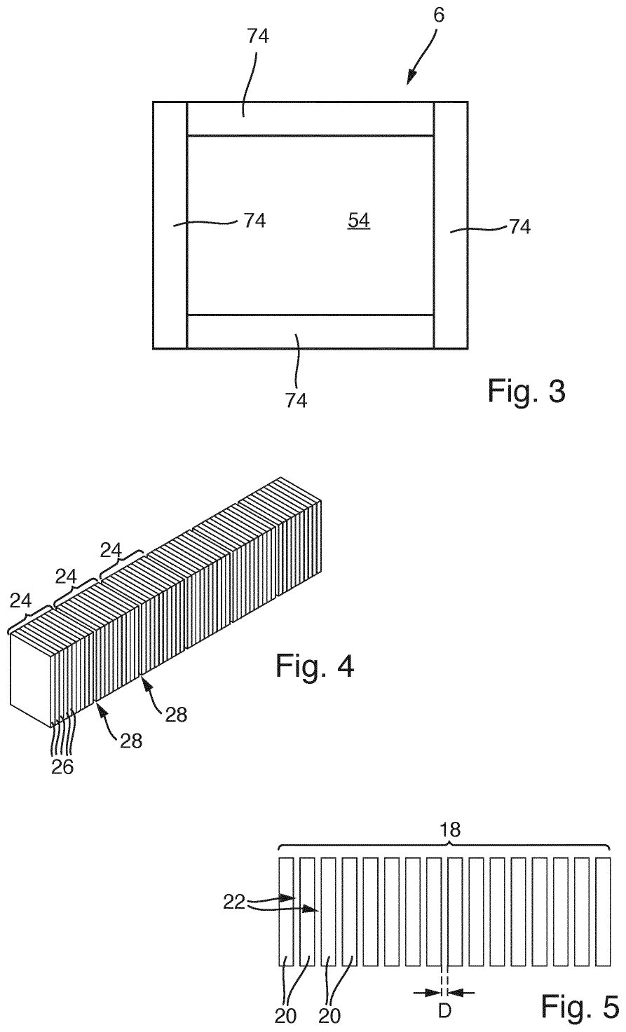

FIG. 3 schematically illustrates one advantageous embodiment of the core 6 of the measuring device 2. It may be seen from FIG. 3 that the core 6 may be formed by four edges 74, specifically two edges 74 each running in the horizontal direction and two edges 74 each running in the vertical direction. Each edge 74 may also be referred to and/or designed as an edge element 74 of the core 6. The edges 74 of the core 6 may be in contact with one another such that the core 6 is formed by the edges 74 in uninterrupted form and completely in the circumferential direction.

It has furthermore proven to be advantageous when the core 6 has at least one section 18 having a plurality of magnetic, in particular ferromagnetic plates 20 that are arranged opposite one another, in particular so as to be parallel, and are each spaced by a gap 22 from plate 20 to plate 20. This advantageous embodiment of a section of the core is illustrated schematically in FIG. 5. Preferably, the plates 20 of the section 18 are not in direct contact with one another. Each pair of plates (pair of plates), arranged opposite one another, of the section 18 is separated by an associated gap 22. The plates 20 of each pair of plates, spaced by a gap 22, of the section 18 are thus arranged in a manner spaced from one another without contact, with a plate distance D between at least 0.001 mm and at most 2.5 mm, preferably between 0.005 mm and 1 mm. The plate distance D is preferably the minimum distance between the plates 20 of the pair of plates. A plurality of gaps 22 therefore also arise in a section 18 in the case of the plurality of magnetic, in particular ferromagnetic plates 20 of the section 18. The plurality of plates 20 and the plurality of gaps 22 make it possible to effectively prevent saturation of the core 6. Each section 18 comprises at least 5 plates, at least 10 plates or at least 20 plates. Provision is preferably made for each section 18 to have at most 500, at most 200 or at most 100 plates.

In one advantageous embodiment, provision may be made for each edge 74 to have at least one section 18 having the plurality of magnetic, in particular ferromagnetic plates 20. However, it is also possible for a single section 18 to extend over the entire length of the respective edge 74. In this case, provision may be made for the core 6 to be formed from four such sections 18, each having a plurality of magnetic, in particular ferromagnetic plates 20.

At least part of a further advantageous embodiment of the core 4 is illustrated schematically in FIG. 4. According to this embodiment, the core 4 has multiple sections 24. Each section 24 in turn has a plurality of magnetic, in particular ferromagnetic plates 26, wherein the plates 26 of the respective section 24 are arranged opposite one another, in particular so as to be parallel, and in direct contact from plate 26 to plate 26. The multiple sections 24 of the core 4 are arranged in succession and arranged in a manner spaced from one another by a gap 28 from section 24 to section 24. Each gap 28 thus separates the plate 26 arranged at one end of a section 24 from an opposing plate 26 of the following section 24. There is no gap between the plates 26 within the respective section 24. On the contrary, the plates 26 within the respective section 24 are arranged in succession without a gap and in direct contact. Each section 24 may for example comprise between 2 and 50 plates, in particular between 5 and 30 plates, preferably between 5 and 15 plates. The plurality of sections 24 and the corresponding plurality of gaps 22 make it possible to effectively prevent saturation of the core 6.

In the last-mentioned embodiment, it is possible for each of the edges 74 illustrated in FIG. 3 to be formed by multiple sections 24. These sections 24 are separated here from section 24 to section 24 by a respective gap 28.

FIG. 7 schematically illustrates the first advantageous embodiment of the current transformer 4. The current transformer 4 includes the measuring device 2 and the differential amplifier 36. A first input connection 38 of the differential amplifier 36 is electrically connected to the first conductor end 14 of the current conductor 12 of the measuring device 2 by way of a shielded first connecting line 40. A second input connection 42 of the differential amplifier 36 is electrically connected to the second conductor end 16 of the current conductor 12 of the measuring device 2 by way of a shielded second connecting line 44. The reference connection 10 of the measuring device 2 is coupled to a predetermined electrical reference potential. The reference potential is preferably ground potential 46.

A differential payload signal generated at the conductor ends 14, 16 by the measuring device 2 is generated by a primary current of a primary current conductor (illustrated), which is guided through the interior space 54 of the measuring device 2. The differential payload signal is transmitted to the two input connections 38, 42 of the differential amplifier 36 by way of the two connecting lines 40, 44. The differential amplifier 36 is designed to generate an output signal at the output connection 60 of the differential amplifier 36 based on a voltage difference at the two input connections 38, 42. The output signal is therefore dependent on the primary current via the payload signal. Preferably, the output signal represents the primary current.

To prevent external electromagnetic interference signals from influencing the measuring device 2, multiple measures have already been explained above. These apply analogously to the measuring device 2 of the current transformer 4. In addition, it should be mentioned that the two connecting lines 40, 44 are shielded in order to be protected from external electromagnetic interference signals. As illustrated purely by way of example in FIG. 7, the connecting lines 40, 44 may be shielded by a common line shield 76. The common line shield 76 is arranged at a distance so as to be electrically isolated from the two connecting lines 40, 44. The common line shield 76 may be formed by a wound and/or braided metal strip.

Provision is preferably furthermore made for the differential amplifier 36 to have an associated shield 52. This shield 52 is referred to as the second shield 52. The second shield 52 may for example be formed by a grating housing. The second shield 52 is preferably arranged and/or designed so as to protect the differential amplifier 36 from external electromagnetic interference signals.

As illustrated purely by way of example in FIG. 7, provision may be made for the second shield 52 and the common line shield 76 to be electrically connected to one another. Provision may furthermore be made for a further electrical connection to be guided from ground potential 46 to the second shield 52 and/or the common line shield 76, such that the second shield 52 and/or the common line shield 76 are and/or is coupled to ground potential 46.

FIG. 8 schematically illustrates a further advantageous embodiment of the current transformer 4. The current transformer 4 corresponds essentially to the current transformer 4 explained above. Reference is therefore made analogously to the corresponding explanations. However, the current transformer 4 illustrated in FIG. 8 differs in that the common line shield 76 is furthermore electrically connected to the first shield 30 of the measuring device 2. Provision is made in particular for there to be an electrical connection between the common line shield 76 and the first protective element 32 of the first shield 32.

FIG. 9 illustrates a further advantageous embodiment of the current transformer 4. The current transformer 4 corresponds essentially to the current transformer 4 explained above. Reference is therefore made analogously to the corresponding explanations above for this current transformer 4. However, the current transformer 4 illustrated in FIG. 9 differs in that the current transformer 4 has the measuring device 2 illustrated in FIG. 6, and not the measuring device 2 from FIG. 1. The current transformer 4 illustrated in FIG. 9 furthermore differs in that each of the two connecting lines 40, 44 has a separate associated line shield 48, 50. The two line shields 48, 50 are preferably coupled separately, as illustrated in FIG. 9, to ground potential 46. Provision is preferably furthermore made for the reference connection 10 to be separate from the line shields 48, 50, such that no direct electrical connection that does not run via ground potential 46 is formed from the reference connection 10 to at least one of the line shields 48, 50. Each of the two line connections 40, 44 may be formed in the manner of a coaxial cable having the associated sheath-side shield 48, 50 that forms the respective line shield 48, 50. Each of the two shields 48, 50 may be formed by a wound and/or braided metal strip.

Provision is preferably furthermore made for the second shield 52 of the differential amplifier 36 to be coupled separately to ground potential 46, wherein the second shield 52 is separate from the two line shields 48, 50, such that no direct electrical connection that does not run via ground potential 46 is formed from the second shield 52 to at least one of the line shields 48, 50.

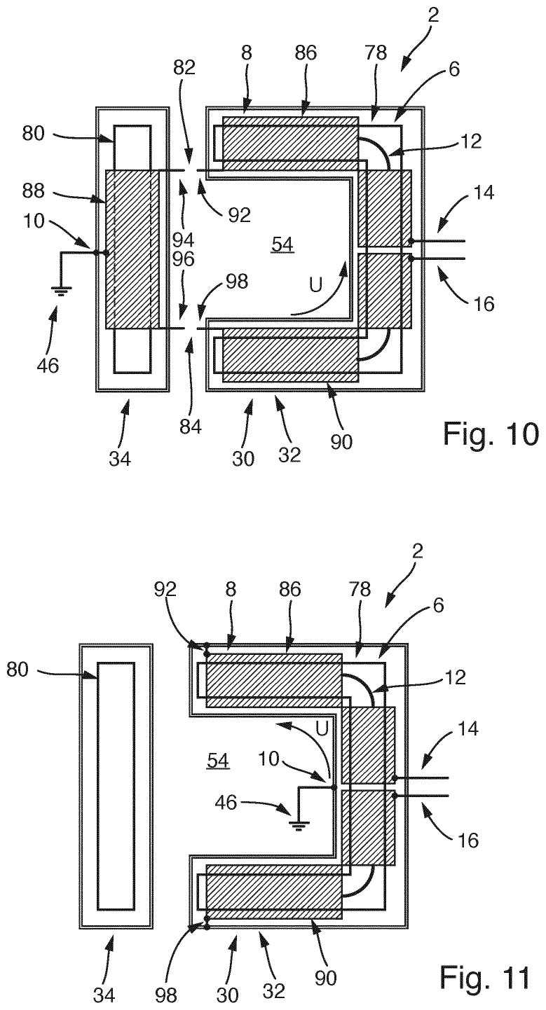

A third advantageous embodiment of the measuring device 2 is illustrated schematically in FIG. 10. This embodiment of the measuring device 2 differs from the first advantageous embodiment (FIG. 1) of the measuring device 2 in terms of the multi-part embodiment of the core 6, the multi-part embodiment of the measuring coil 8 and the multi-part embodiment of the first shield 30. Reference is made to the explanations regarding the first advantageous embodiment of the measuring device 2 for all other advantageous properties, features, advantages and/or effects.

As may be seen from FIG. 10, the core 6 is formed of two parts. The first part 78 of the core 6 is preferably designed as a part 78 of the core 6 with a C-shaped cross section. The second part 80 of the core 6 is preferably designed as a part 80 of the core 6 with an I-shaped cross section. The I-shaped part 80 of the core 6 may be placed onto the limb-shaped ends of the C-shaped part 78 of the core, such that the corresponding limb ends of the C-shaped part 78 of the core 6 are connected by way of the I-shaped part 80 of the core 6. This may result in direct mechanical and/or electrical contact between the I-shaped part 80 and the C-shaped part 78 of the core 6. The I-shaped part 80 may additionally be arranged with respect to the C-shaped part 78 such that the core 6 is formed with a cross section that runs around in the shape of a rectangle.

The multi-part, in particular two-part embodiment of the core 6 offers the advantage that the core 6 is able to be arranged particularly easily around a primary power line, such that the core 6 annularly surrounds the primary power line. In other words, in this case, the primary power line will pass through the interior space 54 formed by the core 6.

FIG. 10 furthermore shows the advantageous embodiment of the measuring coil 8 as a multi-part measuring coil 8. The measuring coil 8 is basically formed by the current conductor 12 wound around the core. The current conductor 12 extends from the first conductor end 14 to the second conductor end 16. In the embodiment illustrated in FIG. 10, the current conductor 12 is detachably interrupted at a first connection point 82 and at the second connection point 84. However, the interruptions at the two connection points 82, 84 are selected only to improve the illustration in FIG. 10 and/or may be used for installation.

The current conductor 12 extends, during practical use of the measuring device 2, in uninterrupted form from the first conductor end 14 to the second conductor end 16. With a first winding section 86 of the measuring coil 8, the current conductor 12 extends from the first conductor end 14 to a first connection end 92. With a second winding section 88 of the measuring coil 8, the current conductor 12 extends from a second connection end 94 to a third connection end 96. With a third winding section 90 of the measuring coil 8, the current conductor 12 extends from a fourth connection end 98 to the second conductor end 16.

The uninterrupted connection of the current conductor 12 may be achieved at the first connection point 82 by connecting the first connection end 92 to the second connection end 94. This may be a materially bonded connection or a detachable connection. The same applies to the second connection point 84. The uninterrupted connection of the current conductor 12 may be achieved at the second connection point 84 by connecting the third connection end 96 to the fourth connection end 98. This may be a materially bonded connection or a detachable connection.

It may also be seen from FIG. 10 that the first shield 30 is designed as a multi-part shield. The shield 30 may include and/or be formed from a first protective element 32 and a second protective element 34. The first protective element 32 may surround the C-shaped part 78 of the core 6 and the first and second winding section 86, 88 of the measuring coil 8 in the shape of a tube. As a result, the first protective element 32 may likewise be designed with a C-shaped cross section. The second protective element 34 may completely surround the I-shaped part 80 of the core 6. The second protective element 34 may thus likewise be designed with an I-shaped cross section.

Preferably, the reference connection 10 is electrically conductively connected to the current conductor 12 centrally between the second connection end 94 and the third connection end 96. If the I-shaped part 80 of the core 6 is placed on the C-shaped part 78 of the core 6 and in the process the abovementioned pairs of connecting ends 92, 94 and 96, 98 are also connected to one other, then this results in the reference connection 10 being electrically conductively connected to the current conductor 12 centrally between the first conductor end 14 and the second conductor end 16.

A fourth advantageous embodiment of the measuring device 2 is illustrated schematically in FIG. 11. This fourth embodiment of the measuring device 2 differs from the third advantageous embodiment of the measuring device 2, as illustrated in FIG. 10, in that the I-shaped part 80 of the core 6 does not carry a winding section, in particular does not carry the second winding section 88. Reference is made to the explanations regarding the first and third advantageous embodiment of the measuring device 2 for all other advantageous properties, features, advantages and/or effects.

As may be seen from FIG. 11, the first connection end 92 in the third advantageous embodiment of the measuring device 2 is not used for the detachable connection to a further connection end, but rather the first connection end 92 is electrically conductively connected to the first protective element 32. The same applies to the fourth connection end 98, which is likewise electrically conductively connected to the first protective element 32. The first protective element 32 is designed to be electrically conductive. The first protective element 32 therefore establishes an electrically conductive connection between the first connection end 92 and the fourth connection end 98. This connection, formed by the first protective element 32, between the two connection ends 92, 98 thus simultaneously forms part of the current conductor 12 that extends from the first conductor end 14 to the second conductor end 16. It has therefore proven to be particularly advantageous when the reference connection 10 is electrically conductively connected to the first protective element 32 centrally between the first connection end 92 and the fourth connection end 98. This ensures that the reference connection 10 is electrically conductively connected to the current conductor 12 centrally between the first conductor end 14 and the second conductor end 16, sections of which current conductor are formed here in particular by the dual function of the first protective element 32.

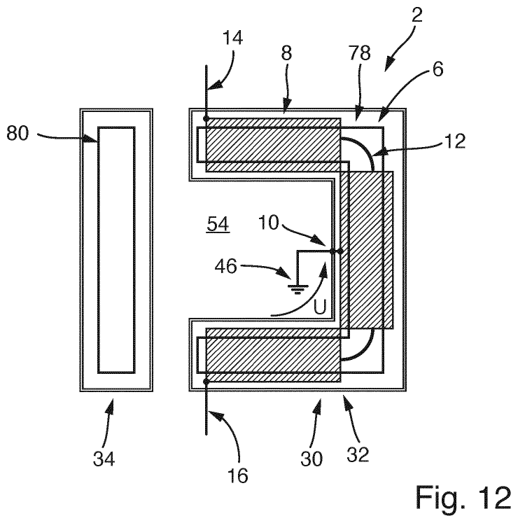

A fifth advantageous embodiment of the measuring device 2 is illustrated schematically in FIG. 12. This fifth embodiment of the measuring device 2 differs from the third and fourth advantageous embodiment of the measuring device 2, as illustrated in FIGS. 10 and 11, through the embodiment of the measuring coil 8. Reference is made to the explanations regarding the first, third and fourth advantageous embodiment of the measuring device 2 for all other advantageous properties, features, advantages and/or effects.

In the fifth advantageous embodiment of the measuring device 2, the measuring coil 8 is formed by the uninterrupted current conductor 12 wound around the core 6, which current conductor extends in uninterrupted form from the first conductor end 14 to the second conductor end 16. No detachable connection points are provided in the current conductor 12. The measuring coil 8 may thereby be implemented in a particularly simple and at the same time imprecise manner. The measuring coil 8 is arranged exclusively on the C-shaped part 78 of the core 6. The reference connection 10 is electrically conductively connected to the current conductor 12 centrally between the first conductor end 14 and the second conductor end 16. The reference connection 10 is preferably also electrically connected to the first protective element 32. It has furthermore proven to be advantageous when the first reference connection 10 is coupled to ground potential 46.

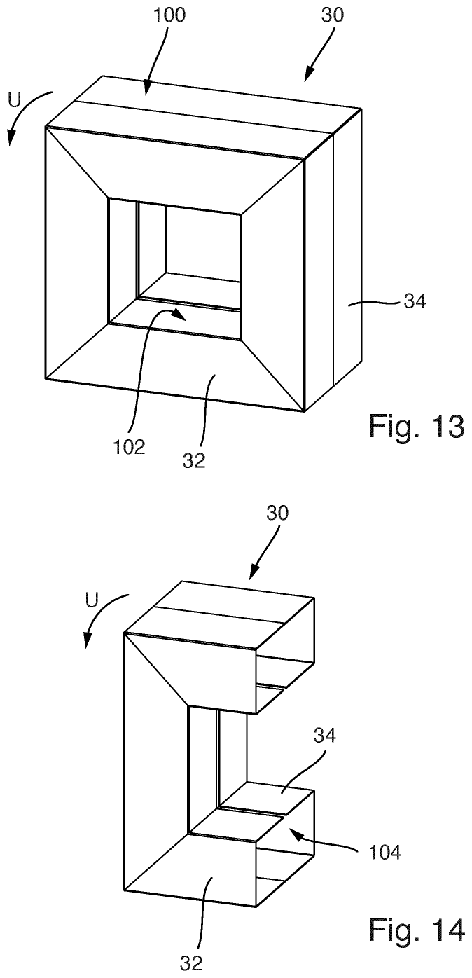

FIG. 13 schematically illustrates a further advantageous embodiment of the first shield 30 for the measuring device 2. The first shield 30 is designed as an annular shield 30, running around in the circumferential direction U of the core 6 and enclosing the core 6 and the measuring coil 8 at least substantially in the shape of a tube. This embodiment of the first shield 30 is also referred to as annular shield 30. The annular shield 30 is formed by two shell-shaped protective elements 32, 34 each running around in the circumferential direction U of the core. These two shell-shaped protective elements 32, 34 form the first and second protective element 32, 34 of the first shield 30.

The first shield 30 from FIG. 13 is illustrated in a sectional illustration in FIG. 14. As may be seen from looking at FIGS. 13 and 14 together, the first protective element 32 and the second protective element 34 are designed to be mirror-symmetrical and/or shell-shaped, in particular annular shell-shaped. Each of the two protective elements 32, 34 runs around in the circumferential direction U of the core 6 in the shape of a rectangle. The outer contour 100 of the annular shield 30 and the outer contour 100 of each of the two shell-shaped protective elements 32, 34 are each rectangular, at least in terms of their cross section. The inner contour 102 formed by the annular shield 30 is likewise rectangular, at least in terms of its cross section. Each of the two shell-shaped protective elements 32, 34 forms part of the inner contour 102, such that the inner contour formed by each of the two protective elements 32, 34 is also rectangular, at least in terms of its cross section. The embodiment of the first shield 30 illustrated in FIGS. 13 and 14 offers the advantage that the two shell-shaped protective elements 32, 34 are able to be pushed over the core 6 and the measuring coil 8 from the front and rear, respectively, such that the shield 30 forms a closed protective space 104 in which both the core 6 and the measuring coil 8 are arranged (not illustrated). This makes it possible to ensure effective protection against electromagnetic interference.

In addition, it should be pointed out that “having” does not exclude any other elements or steps and “a” or “an” does not exclude a multiplicity. Furthermore, it should be pointed out that features that have been described with reference to one of the above exemplary embodiments may also be used in combination with other features of other exemplary embodiments described above. Reference signs in the claims should not be construed as a limitation.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

B Protective distance
D Plate distance
K Second minimum distance
M Minimum distance
R Radial direction
U Circumferential direction
2 Measuring device
4 Current transformer
6 Core
8 Measuring coil
10 Reference connection
12 Current conductor
14 First conductor end
16 Second conductor end
18 Section
20 Plate
22 Gap
24 Section
26 Plate
28 Gap
30 First shield
32 First protective element
34 Second protective element
36 Differential amplifier
38 First input connection
40 First connecting line
42 Second input connection
44 Second connecting line
46 Ground potential
48 First line shield
50 Second line shield
52 Second shield
54 Interior space
56 First partial length
58 Second partial length
60 Output connection
62 Winding section
64 First winding section
66 Second winding section
68 Common protective element
70 First recess
72 Second recess
74 Edge
76 Common line shield
78 First part of the core
80 Second part of the core
82 First connection point
84 Second connection point
86 First winding section
88 Second winding section
90 Third winding section
92 First connection end
94 Second connection end
96 Third connection end
98 Fourth connection end
100 Outer contour
102 Inner contour
104 Protective space

1. A measuring device for a current transformer, the measuring device comprising:
a surrounding core;
a measuring coil; and
a reference connection,
wherein the measuring coil comprises a current conductor wound around the surrounding core that extends from a first conductor end to a second conductor end, and
wherein the reference connection is electrically conductively connected to the current conductor centrally between the first conductor end and the second conductor end.

2. The measuring device as claimed in claim 1, wherein the reference connection is electrically connected to the current conductor such that a first impedance of the current conductor between the reference connection and the first conductor end and a second impedance of the current conductor between the reference connection and the second conductor end are identical or have a maximum deviation of 5%.

3. The measuring device as claimed in claim 1, wherein the reference connection is connected to a predetermined electrical reference potential.

4. The measuring device as claimed in claim 1, wherein the measuring coil is arranged in a manner distributed symmetrically with respect to a radial plane of the surrounding core.

5. The measuring device as claimed in claim 1, wherein the surrounding core comprises or is formed from ferromagnetic material.

6. The measuring device as claimed in claim 1, wherein the surrounding core is of multi-part design.

7. The measuring device as claimed in claim 1, wherein the measuring coil is of multi-part design.

8. The measuring device as claimed in claim 1, wherein the surrounding core comprises at least one section comprising a plurality of ferromagnetic plates that are arranged opposite one another so as to be parallel, and are each spaced by a gap from plate to plate.

9. The measuring device as claimed in claim 1, wherein the surrounding core comprises multiple sections each having a plurality of magnetic ferromagnetic plates, wherein the plates of a respective section are arranged opposite one another so as to be parallel, and in direct contact from plate to plate, and wherein the sections of the surrounding core are arranged in succession and spaced by a gap from section to section.

10. The measuring device as claimed in claim 8, wherein each instance of the gap is formed as an air gap or a spacer is inserted into each gap.

11. The measuring device as claimed in claim 10, wherein each instance of the spacer is formed by a non-magnetic material.

12. The measuring device as claimed in claim 8, wherein the plates of each pair of plates spaced by the respective gap are arranged in a manner spaced from one another without contact, with a plate distance D between at least 0.001 mm and at most 2.5 mm.

13. The measuring device as claimed in claim 1, wherein the measuring device comprises a first shield comprising a first protective element.

14. The measuring device as claimed in claim 13 wherein the first protective element is designed as an electrically conductive protective element that is arranged outside the surrounding core and the measuring coil and that runs around at least substantially completely in the circumferential direction U of the core.

15. The measuring device as claimed in claim 14 wherein the first shield comprises a second protective element that is an electrically conductive protective element that is arranged inside the surrounding core and the measuring coil and that runs around in the circumferential direction of the surrounding core.

16. The measuring device as claimed in claim 15 wherein the first shield is an annular shield that runs around in the circumferential direction of the core and that encloses the surrounding core and the measuring coil in the shape of a tube, wherein the annular shield is formed of two shell-shaped protective elements, each running around in the circumferential direction of the surrounding core which form the first protective element and the second protective element.

17. The measuring device as claimed in claim 16 wherein an outer contour of the annular shield or of each shell-shaped protective element is rectangular, or wherein an inner contour formed by the annular shield or by each shell-shaped protective element is rectangular.

18. The measuring device as claimed in claim 13, wherein the first protective element and the second protective element are electrically connected to one another or are formed integrally as a common protective element.

19. The measuring device as claimed in claim 13, wherein a protective distance between the surrounding core or the measuring coil, on the one hand, and the at least one protective element of the first shield, on the other hand, is predetermined such that a predetermined electrical capacitance is formed between the core or the measuring coil, on the one hand, and the first shield, on the other hand.

20. The measuring device as claimed in claim 1, wherein the measuring device is configured to be operated as an infeed device, such that a current is feedable into a primary current conductor guided through the interior space formed by the surrounding core.

21. A current transformer, the current transformer comprising:
the measuring device as claimed in claim 1, and
a differential amplifier,
wherein a first input connection of the differential amplifier is electrically connected to the first conductor end of the current conductor of the measuring device by way of a shielded first connecting line,
wherein a second input connection of the differential amplifier is electrically connected to the second conductor end of the current conductor of the measuring device by way of a shielded second connecting line, and
wherein the reference connection is coupled to a predetermined electrical reference potential.

22. The current transformer as claimed in claim 21 wherein the reference connection is coupled to ground potential.

23. The current transformer as claimed in claim 21, wherein each of the two connecting lines has an associated line shield, each of which is coupled to ground potential, wherein the reference connection is separate from the line shields such that no direct electrical connection that does not run via ground potential is formed from the reference connection to at least one of the line shields.

24. The current transformer as claimed in claim 21, wherein the differential amplifier has a second shield that is coupled to ground potential, wherein the second shield is separate from the line shields such that no direct electrical connection that does not run via ground potential is formed from the second shield to at least one of the line shields.
